(19) United States
(12) Patent Application Publication
(10) Pub. No.: US 2008/0043829 A1
(43) Pub. Date: Feb. 21, 2008

(54) Noise Power Estimate Based Equalizer Lock Detector

(76) Inventors: Dong-Chang Shiue, Carmel, IN (US); Aaron Reel Bouillet, Noblesville, IN (US); Maxim B. Belotserkovsky, Carmel, IN (US)

Correspondence Address: THOMSON LICENSING LLC, Two Independence Way, Suite 200, PRINCETON, NJ, 08540, US

(21) Appl. No.: 11/596,158

(22) PCT Filed: Apr. 18, 2005
(86) PCT No.: PCT/US05/13145

§ 371 Date: Nov. 10, 2006

Related U.S. Application Data
(60) Provisional application No. 60/570,292, filed on May 12, 2004.
(60) Provisional application No. 60/570,290, filed on May 12, 2004.

(51) Int. Cl. H03H 7/40

(52) U.S. Cl. 375/232

(57) ABSTRACT

An ATSC (Advanced Television Systems Committee-Digital Television) receiver comprises an equalizer (220) and a lock detector (230). The equalizer (220) provides a sequence of received signal points (221) from a constellation space, the constellation space having an inner region and one, or more, outer regions. The lock detector (230) determines equalizer lock as a function of a noise power estimate developed from the number of received signal points falling in the one, or more, outer regions (305).

### BACKGROUND OF THE INVENTION

The present invention generally relates to communications systems and, more particularly, to a receiver.

In modern digital communication systems like the ATSC-DTV (Advanced Television Systems Committee-Digital Television) system (e.g., see, United States Advanced Television Systems Committee, “ATSC Digital Television Standard”, Document A/53, Sep. 16, 1995 and “Guide to the Use of the ATSC Digital Television Standard”, Document A/54, Oct. 4, 1995), advanced modulation, channel coding and equalization are usually applied. In the receiver, the equalizer processes the received signal to correct for distortion and is generally a DFE (Decision Feedback Equalizer) type or some variation of it.

In order to determine whether the equalizer is properly equalizing the received signal, i.e., whether or not the equalizer has converged, or “locked”, onto the received signal, the receiver typically includes a “lock detector.” If the lock detector indicates that the equalizer has not converged, or is unlocked, the receiver may, e.g., reset the equalizer and restart signal acquisition.

Unfortunately, conventional equalizer lock detection methods are sensitive to noise and, as such, can generate false lock detections, which can further impact overall receiver performance.

### SUMMARY OF THE INVENTION

We have observed that it is possible to further improve the accuracy of equalizer lock detection, especially in low signal-to-noise ratio (SNR) environments, by taking into account the statistical properties of the type of noise, e.g., Additive White Gaussian Noise, present on the channel. In particular, and in accordance with the principles of the invention, a receiver determines equalizer lock as a function of a noise power estimate, which is determined as a function of the distribution of received signal points in a constellation space, wherein different weights are given to different regions of the constellation space.

In an embodiment of the invention, an ATSC receiver comprises an equalizer and a lock detector. The equalizer provides a sequence of received signal points from a constellation space, the constellation space having an inner region and one, or more, outer regions. The lock detector determines equalizer lock as a function of a noise power estimate developed from the number of received signal points falling in the one, or more, outer regions.

In another embodiment of the invention, an ATSC receiver comprises an equalizer and a lock detector. The equalizer provides a sequence of received signal points from a constellation space, the constellation space having an inner region and one, or more, outer regions. The lock detector determines equalizer lock as a function of a signal-to-noise power ratio developed from the number of received signal points falling in the one, or more, outer regions.

### BRIEF DESCRIPTION OF THE DRAWINGS

FIGS. 1 and 2 illustrate received signal probability distribution functions for different levels of noise power;

FIG. 3 shows an illustrative high-level block diagram of a receiver embodying the principles of the invention;

FIG. 4 shows an illustrative portion of a receiver embodying the principles of the invention;

FIGS. 5 and 6 show an illustrative flow charts in accordance with the principles of the invention;

FIG. 7 further illustrates the inventive concept for a one-dimensional symbol constellation;

FIGS. 8 and 9 further illustrate the inventive concept for a two-dimensional symbol constellation;

FIGS. 10 and 11 show other illustrative flow charts in accordance with the principles of the invention; and

FIG. 12 shows another illustrative embodiment in accordance with the principles of the invention.

### DETAILED DESCRIPTION

Other than the inventive concept, the elements shown in the figures are well known and will not be described in detail. Also, familiarity with television broadcasting and receivers is assumed and is not described in detail herein. For example, other than the inventive concept, familiarity with current and proposed recommendations for TV standards such as NTSC (National Television Systems Committee), PAL (Phase Alternation Lines), SECAM (SEquential Couleur Avec Memoire) and ATSC (Advanced Television Systems Committee) (ATSC) is assumed. Likewise, other than the inventive concept, transmission concepts such as eight-level vestigial sideband (8-VSB), Quadrature Amplitude Modulation (QAM), and receiver components such as a radio-frequency (RF) front-end, or receiver section, such as a low noise block, tuners, demodulators, correlators, leak integrators and squarers is assumed. Similarly, formatting and encoding methods (such as Moving Picture Expert Group (MPEG)-2 Systems Standard (ISO/IEC 13818-1)) for generating transport bit streams are well-known and not described herein. It should also be noted that the inventive concept may be implemented using conventional programming techniques, which, as such, will not be described herein. Finally, like-numbers on the figures represent similar elements.

Assuming an AWGN (Additive White Gaussian noise) transmission channel, in digital communications the demodulated received signal can be represented as
r(nT)=s(nT)+w(nT); n=0,1,2,3 . . . (1)
where T is the sample time, s(nT) is the transmitted symbol, and w(nT) is the additive white Gaussian noise of the channel. As known in the art, the Gaussian distribution is defined as

$$f ( x ) = \frac{1}{σ \sqrt{2 π}} {ⅇ}^{- {( x - μ )}^{2} / 2 {σ}^{2}} , \qquad ( 2 )$$

where σ² is the variance and μ is the mean. The above expressions apply to both I (in-phase) and Q (quadrature) data if I and Q are statistically independent.

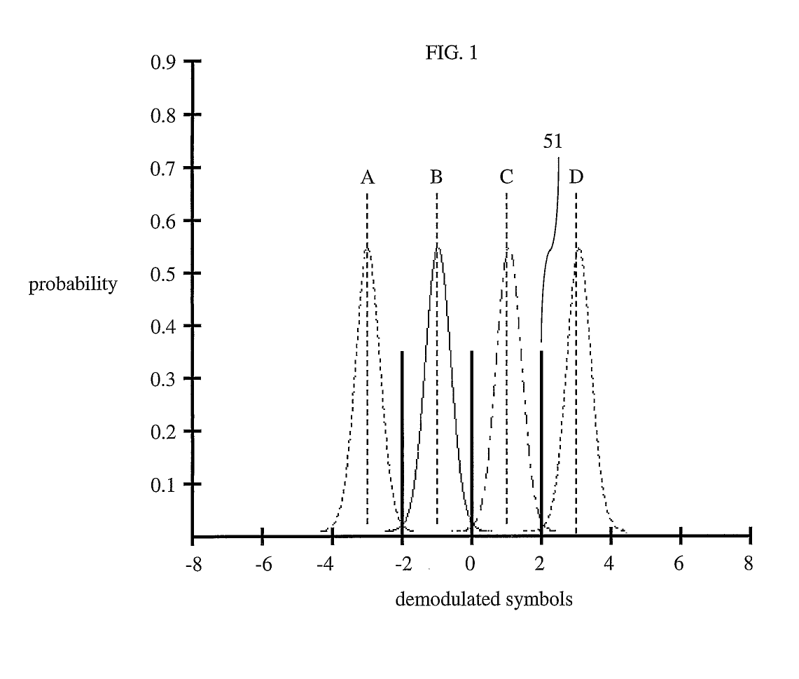

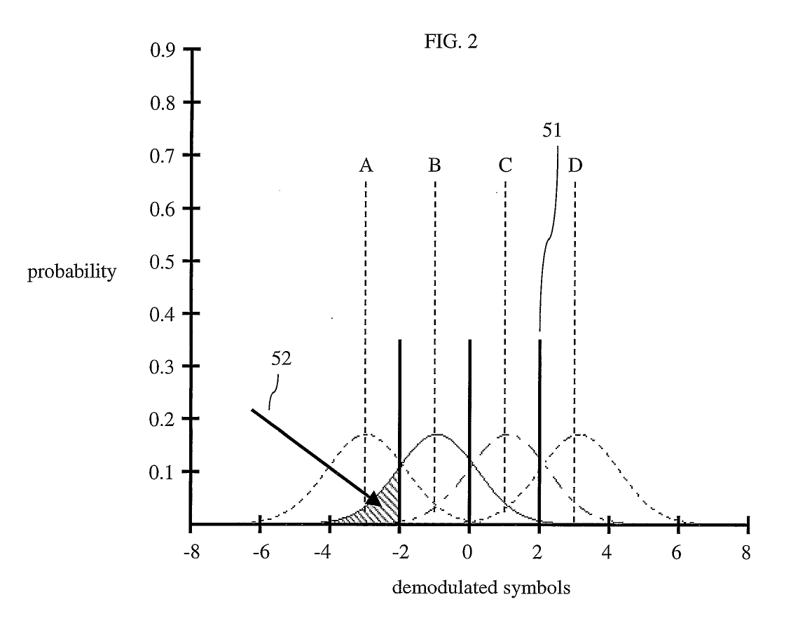

Now, for simplicity, consider a transmitter that transmits symbols taken from a constellation space comprising four symbols: A, B, C and D and that each of these symbols is assigned values, −3, −1, 1 and 3, respectively. The effect of different types of AWGN channels on this transmitted signal is shown in FIGS. 1 and 2. In particular, these figures show the resulting probability distribution function (pdf) of the demodulated received signal, r(nT), for different values of noise power (variance).

Turning first to FIG. 1, this figure shows the demodulated received signal pdf for a noise power of σ²=0.5. The shorter vertical solid lines of FIG. 1, as represented by line 51, are illustrative slice boundaries for the receiver to “slice” the demodulated received signal point and thereby determine the received symbol. As known in the art, a receiver performs slicing (also referred to as “hard decoding”) to select what symbol may actually have been transmitted. Generally, slicing selects as the received symbol that symbol geometrically closest in value to the received signal point. In the context of FIG. 1, slicing is performed according to the following rules:

$${S}_{sliced} = \begin{matrix}- 3 if r < - 2 & Symbol A received , \\ - 1 if - 2 <= r < 0 & Symbol B received , \\ 1 if 0 <= r < 2 & Symbol C received ; and \\ 3 if r > 2 & Symbol D received ;\end{matrix} \qquad ( 3 )$$

where, r is the value of the received signal point (including any corruption due to noise) and S_{sliced} is the corresponding selected symbol. For example, if the received signal point has a value of (−2.5), then the receiver would select symbol A as the received symbol. It can be observed from FIG. 1, that the noise power is insignificant and therefore the sliced data will almost always be right, i.e., almost always correspond to the symbol actually transmitted.

However, FIG. 2, illustrates the impact of more noise power on the transmitted signal. In particular, FIG. 2 shows the demodulated received signal pdf for a noise power of σ²=3.0. Again, FIG. 2 also shows the slicing boundaries as represented by line 51. Now, it should be observed that the noise power is large enough to cause certain demodulated received signal points to cross over to the decision region of another symbol. This results in the receiver making slicing errors. For example, again assume that the received signal point has a value of (−2.5). In this case, as before, the receiver will select symbol A as the received symbol. However, now there is a higher probability that this sliced decision is wrong. As indicated by arrow 52 of FIG. 2, the shaded area shows that the receiver may be making a slicing error since there is a significant probability that symbol B may have been transmitted instead of symbol A. These slicing errors or decision errors can incur less reliable communication links and, in some cases, cause communication link to fail.

We have observed that it is possible to further improve the accuracy of equalizer lock detection, especially in low signal-to-noise ratio (SNR) environments, by taking into account the above-described statistical properties of the type of noise, e.g., Additive White Gaussian Noise, present on the channel. In particular, we have observed from FIG. 2 that a demodulated received signal point is unlikely to cross over two or more slicing boundaries. For instance, a transmitted symbol A even corrupted by noise is not likely to be misinterpreted by the receiver as symbol C or symbol D. Thus, we have further observed that the receiver is less likely to be wrong in outer regions of the constellation space versus inner regions of the constellation space. For example, in the decision region for symbol A in FIG. 2, the receiver decides that symbol A was received even though there is a probability that symbol B was actually transmitted. In contrast, consider the decision region for inner symbol C. Here, the receiver decides that symbol C was received—yet two other symbols, B or D, may actually have been transmitted. As such, in the context of FIG. 2, the receiver is less likely to be wrong in the outer symbol regions, i.e., where r≦−3 and r≧3.

In view of the above, those regions, or portions, where the receiver is less likely to be wrong are the regions where the equalizer lock detector should operate. Therefore, and in accordance with the principles of the invention, a receiver determines equalizer lock as a function of a noise power estimate, which is determined as a function of the distribution of received signal points in a constellation space, wherein different weights are given to different regions of the constellation space.

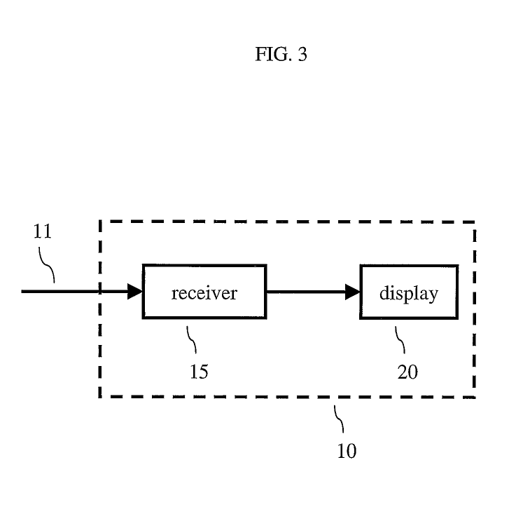

A high-level block diagram of an illustrative television set 10 in accordance with the principles of the invention is shown in FIG. 3. Television (TV) set 10 includes a receiver 15 and a display 20. Illustratively, receiver 15 is an ATSC-compatible receiver. It should be noted that receiver 15 may also be NTSC (National Television Systems Committee)-compatible, i.e., have an NTSC mode of operation and an ATSC mode of operation such that TV set 10 is capable of displaying video content from an NTSC broadcast or an ATSC broadcast. For simplicity in describing the inventive concept, only the ATSC mode of operation is described herein. Receiver 15 receives a broadcast signal 11 (e.g., via an antenna (not shown)) for processing to recover therefrom, e.g., an HDTV (high definition TV) video signal for application to display 20 for viewing video content thereon.

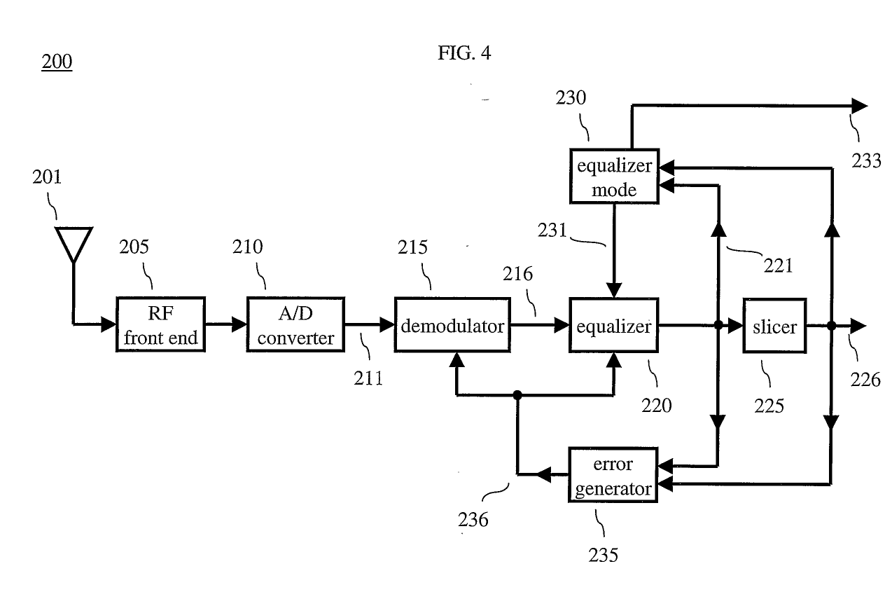

Referring now to FIG. 4, an illustrative embodiment of a portion 200 of receiver 15 in accordance with the principles of the invention is shown. Portion 200 comprises antenna 201, radio frequency (RF) front end 205, analog-to-digital (A/D) converter 210, demodulator 215, equalizer 220, slicer 225, equalizer mode element 230 and error generator 235. Other than the inventive concept, the functions of the various elements shown in FIG. 4 are well known and will only be described very briefly herein. Further, specific algorithms for adapting equalizer coefficients (not shown) of equalizer 220, such as the least-mean square (LMS) algorithm, the Constant Modulus Algorithm (CMA) and the Reduced Constellation Algorithm (RCA) are known in the art and not described herein.

RF front end 205 down-converts and filters the signal received via antenna 201 to provide a near base-band signal to A/D converter 210, which samples the down converted signal to convert the signal to the digital domain and provide a sequence of samples 211 to demodulator 215. The latter comprises automatic gain control (AGC), symbol timing recovery (STR), carrier tracking loop (CTL), and other functional blocks as known in the art for demodulating signal 211 to provide demodulated signal 216, which represents a sequence of signal points in a constellation space, to equalizer 220. The equalizer 220 processes demodulated signal 211 to correct for distortion, e.g., inter-symbol interference (ISI), etc., and provides equalized signal 221 to slicer 225, equalizer mode element 230 and error generator 235. Slicer 225 receives equalized signal 221 (which again represents a sequence of signal points in the constellation space) and makes a hard decision (as described above) as to the received symbol to provide a sequence of sliced symbols, via signal 226, occurring at a symbol rate 1/T. Signal 226 is processed by other parts (not shown) of receiver 15, e.g., a forward error correction (FEC) element, as well as equalizer mode element 230 and error generator 235 of FIG. 4. As known in the art, error generator 235 generates one, or more, error signals 236 for use, e.g., in correcting for timing ambiguities in demodulator 215 and for adapting, or adjusting, filter (tap) coefficient values of equalizer 220. For example, error generator 235 in some instances measures the difference, or error, between equalized signal points and the respective sliced symbols for use in adapting the filter coefficients of equalizer 220. Like error generator 235, equalizer mode element 230 also receives the equalized signal points and the respective sliced symbol, via signals 221 and 226, respectively. Equalizer mode element 230 uses these signals to determine the equalizer mode, which is controlled via mode signal 231. Equalizer 220 can be operated in a blind mode (use of the CMA or RCA algorithm) or in a decision-directed mode (the LMS algorithm) as known in the art.

In addition, and in accordance with the principles of the invention, equalizer mode element 230 (also referred to herein as a lock detector) provides lock signal 233. The latter represents whether or not equalizer 220 has converged. For the sake of simplicity, the following description is limited to one- and two-dimensional symbol constellations. However, the inventive concept is not so limited and can be readily extended to multi-dimensional constellations.

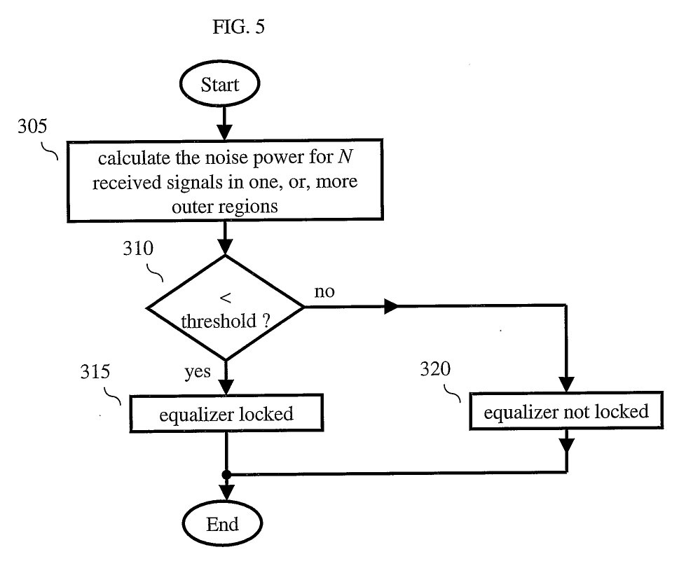

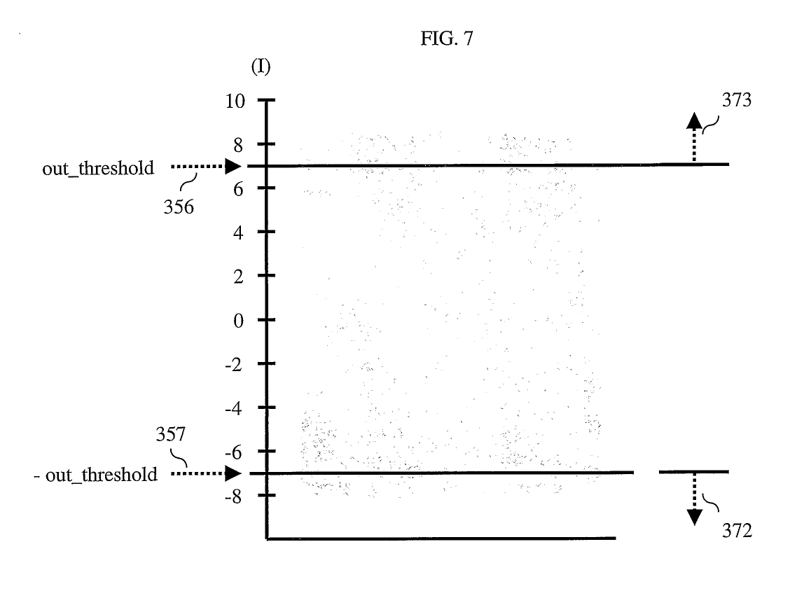

Turning now to FIG. 5, an illustrative flow chart in accordance with the principles of the invention is shown. The flow chart of FIG. 5 is, e.g., illustratively performed by equalizer mode element 230. At this point reference should also be made to FIG. 7, which illustrates operation of the inventive concept with respect to a one-dimensional M-VSB symbol constellation as known in the art, where M=8. In particular, FIG. 7 shows a plot of the equalizer output signal 221 in a low SNR environment. As can be observed from FIG. 7, two outer regions of the constellation have been defined as indicated by dotted line arrows 356 and 357. In particular, the boundary of one, or more, outer regions of the constellation space is indicated by the value of out_threshold. For the 8-VSB symbol constellation, there is a positive out_threshold, represented by dotted arrow 356, e.g., a value of 7.0, and a negative out_threshold, represented by dotted arrow 357, e.g., a value of (−7.0). As such, the magnitude of out_threshold is 7.0. It should be noted that although the inventive concept is illustrated in the context of symmetrical values, the inventive concept is not so limited. As noted above, the value of out_threshold represents the start of one, or more, outer regions of the constellation space. The outer regions of the 8-VSB constellation space shown in FIG. 7 are indicated by the direction of dotted line arrows 372 and 373. As such, received signal points having a magnitude greater than or equal to out_threshold are considered outer received signal points, i.e.,
|Eq_outₙ|≧out_thresh, (4)
Where, Eq_outₙ represents a received signal point provided by equalizer output signal 221 at a time, n.

Returning to FIG. 5, in step 305, equalizer mode element 230 calculates the noise power estimate, P_{w}, for N outer received signal points. As noted above, in the context of FIG. 7, the outer regions of the 8-VSB constellation space are indicated by the direction of dotted line arrows 372 and 373. For a one-dimensional 8-VSB constellation, the noise power estimate is described in the following equations:

$$\begin{matrix}{e}_{n} = {Eq\_out}_{n} - {S\_out}_{n} ; and & ( 5 ) \\ {P}_{w} = \frac{1}{N} {\sum }_{n = 1}^{N} {\vert {e}_{n} \vert}^{2} . & ( 6 )\end{matrix}$$

where only outer received signal points are used in equations (5) and (6). It should be noted that equation (5) represents the error signal, eₙ, between a received signal point as provided by equalizer 220 (signal 221) and the respective sliced symbol as provided by slicer 225 (signal 226).

In step 310, equalizer mode element 230 determines if the value for P_{w} is less than a threshold value. It should be noted that the threshold value may be programmable. If the value of P_{w} is not less than the threshold value, then, in step 320, equalizer mode element 230 determines that the equalizer is not locked and provides lock signal 233 with an illustrative value representing a logical “0”. However, if the value of P_{w} is less than the threshold value, then, in step 315, equalizer mode element 230 determines that the equalizer is locked and provides lock signal 233 with an illustrative value representing a logical “1”. For example, if a lock is declared, then equalizer 220 can be directed to go into a decision-directed mode of operation from a blind mode of operation.

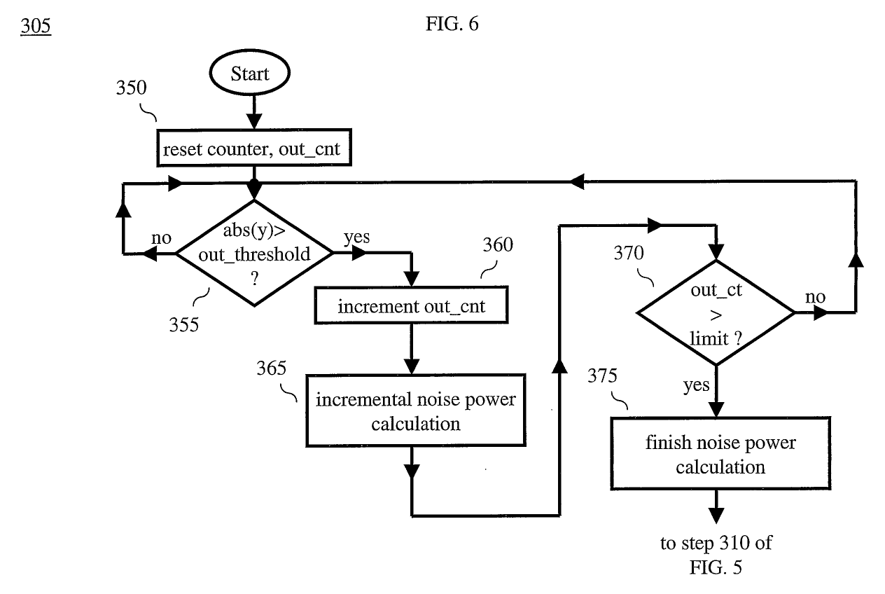

Turning now to FIG. 6, a more detailed flow chart for use in step 305 of FIG. 5 is shown. Illustratively, the following parameters are defined: out_cnt and y. The variable out_cnt tracks the number of received signal points that fall in an outer region of the constellation space. The value of y represents the equalizer output signal 221 of FIG. 4 (also referred to above as Eq_outₙ). In step 350 of FIG. 6, the counter, out_cnt is reset to a value of zero. In step 355, the absolute value of y, abs(y), is compared to the magnitude of out_threshold to determine if the received signal point lies in an outer region of the constellation space. If the received signal point does not lie in an outer region of the constellation space, then execution continues at step 355 with the next received signal point. However, if the received signal point does lie in an outer region of the constellation space, the value of out_cnt is incremented in step 360 and, in step 365, an incremental noise power calculation, e.g., equation (4), is performed for the received signal point. In step 370, the value of out_cnt is compared to a limit value (e.g., limit=2048). If the value of out_cnt does not exceed the limit value, then execution returns to step 355 to evaluate the next received signal point. However, if the value of out_cnt does exceed the limit value, i.e., N outer received signal points have been processed (e.g., N=2048), then the noise power calculation is finished in step 375, e.g., equation (5) is performed with respect to the N outer received signal points, and execution proceeds with step 310 of FIG. 5 to determine if equalizer 220 is locked or not locked.

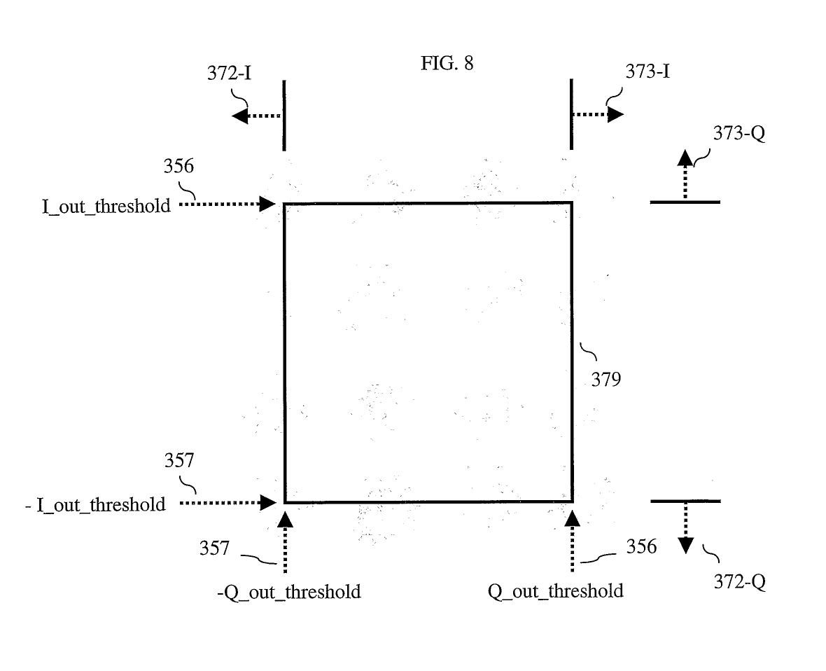

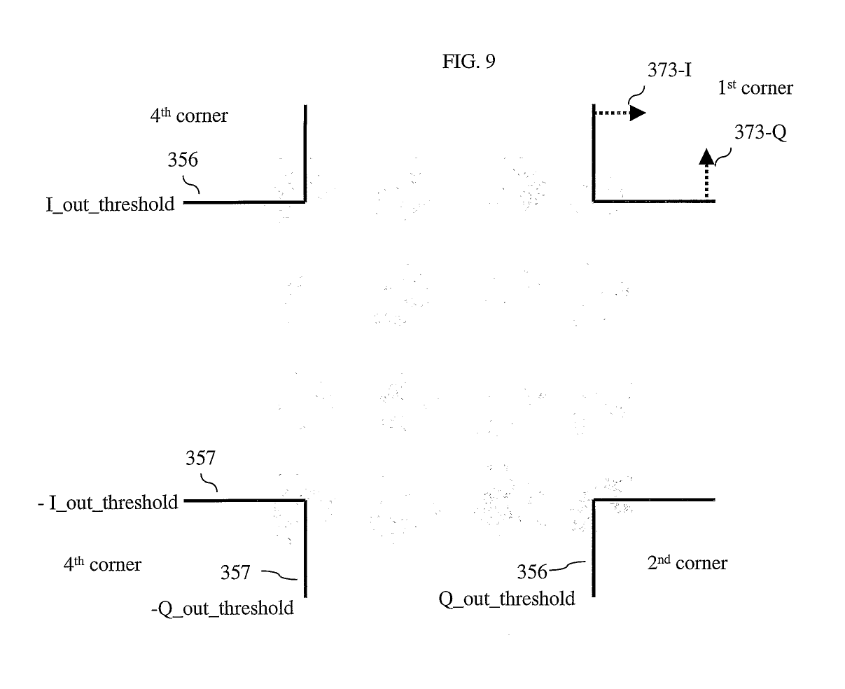

Further illustrations of the inventive concept are shown in FIGS. 8 and 9. These figures illustrate plots of the equalizer output signal 221 in low SNR environments for a two-dimensional M-QAM (quadrature amplitude modulation) symbol constellation as known in the art, where M=16, i.e.,
Eq_outₙ=Iₙ+j*Qₙ, (7)
where Eq_outₙ corresponds to the earlier described r(nT) and is output signal 221 of equalizer 220 at a time n, I is the in-phase component and Q is the quadrature component. For clarity, the in-phase (I) and quadrature (Q) axes are not shown. In the context of FIGS. 8 and 9, several approaches are possible. For example, with respect to the above-described flow charts of FIGS. 5 and 6, (I) and (Q) components of received signal points can be individually counted. It can be observed from FIGS. 8 and 9 that out_thresholds of the constellation space are defined for each dimension (e.g., 372-I, 373-I, 372-Q, 373-Q, etc.) and, e.g., a received signal point is an outer received signal point if:
|Iₙ|≧I_out_thresh, or |Qₙ≧Q_out_thresh. (8)

As in FIG. 7, the outer regions of the constellation space are in the direction of arrows 372 and 373 in both FIGS. 8 and 9. It should be noted in FIG. 8 that the outer region of the constellation space is that area outside of rectangle 379, while in FIG. 9, the outer region of the constellation space is defined as four corner regions. A received signal point lies in a corner region if:
|Iₙ|≧I_out_thresh AND |Qₙ|≧Q_out_thresh. (9)
However, the inventive concept is not so limited and other shapes for the outer region are possible.

It should also be noted with respect to FIG. 7 that since the slicer output symbol, S_out, is a constant in a VSB-based system (because only outer symbols are used), an alternative equation replacing P_{w} can be expressed as,

$${S}_{w} = \frac{1}{N} {\sum }_{n = 1}^{N} {\vert {Eq\_out}_{n} \vert}^{2} . \qquad ( 10 )$$

Equation (10) also applies to a QAM system since the average signal power of the outer symbols is also a constant value. Equation (10) computes the total power of the outer received signal points including noise. Assuming the noise maintains a constant value, the above calculation will become smaller as the equalizer converges. In accordance with the principles of the invention, it is the trend of S_{w} or P_{w} that is used to decide the equalizer state—locked, converging, diverging, or un-locked.

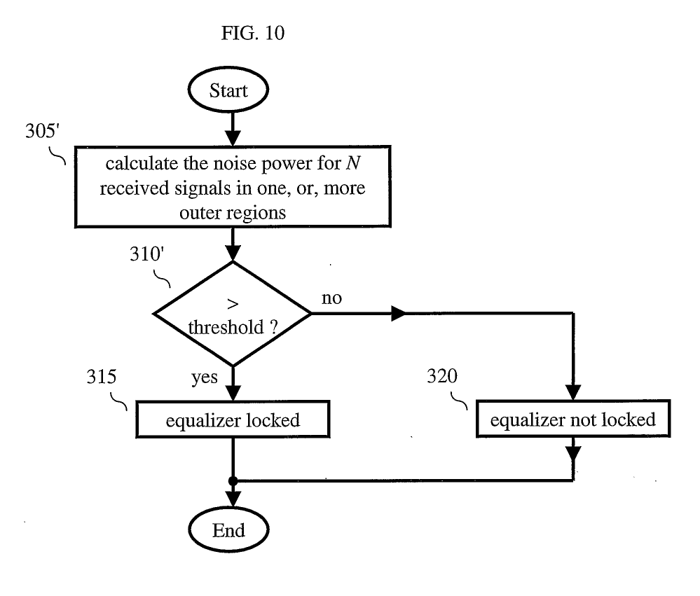

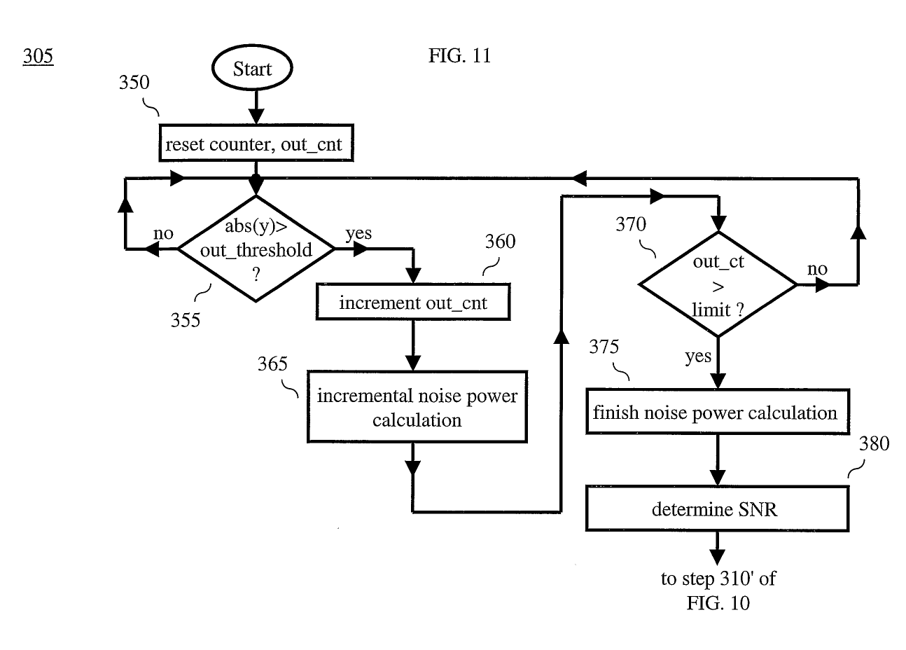

In accordance with another embodiment of the invention, equalizer lock detection is determined as a function of the above-described noise power estimate by using a signal-to-noise ratio (SNR) estimate for the received signal. In particular, after collecting N outer received signal points, the noise power estimate, P_{w}, is then divided by the signal power S_{w}, i.e.,

$$SNR = 10 ⨯ {log}_{10} \frac{{P}_{w}}{{S}_{w}} ( in dB ) . \qquad ( 11 )$$

Where, the signal power, S_{w}, is defined as:

$${S}_{w} = \frac{1}{M} {\sum }_{i = 1}^{M} {\vert si \vert}^{2} , \qquad ( 12 )$$

where sᵢ is the i^{th} symbol and M is the number of symbols in the constellation space, e.g., M=16 for a 16-QAM system, M=64 for a 64-QAM system and M=8 for an 8-VSB system. In the context of the above-described use of corner regions, if N is large enough (e.g., N=8192 outer received signal points), then calculated SNR from equation (11) is a statistically good estimate for use in determining equalizer lock. This variation is shown in the flow charts of FIGS. 10 and 11, which are similar to FIGS. 5 and 6 except for the inclusions of steps 305′ and 310′ (in FIG. 10) and step 375 (in FIG. 11). In particular, like step 305 of FIG. 5, step 305′ of FIG. 10 is shown in more detail in FIG. 11. The latter is similar to FIG. 6 except for the inclusion of step 375, which determines the SNR in accordance with equations (11) and (12), above. Returning to FIG. 10, step 310′ is similar to step 310 of FIG. 5 except that the equalizer is determined to be locked if the SNR is greater than a threshold SNR value.

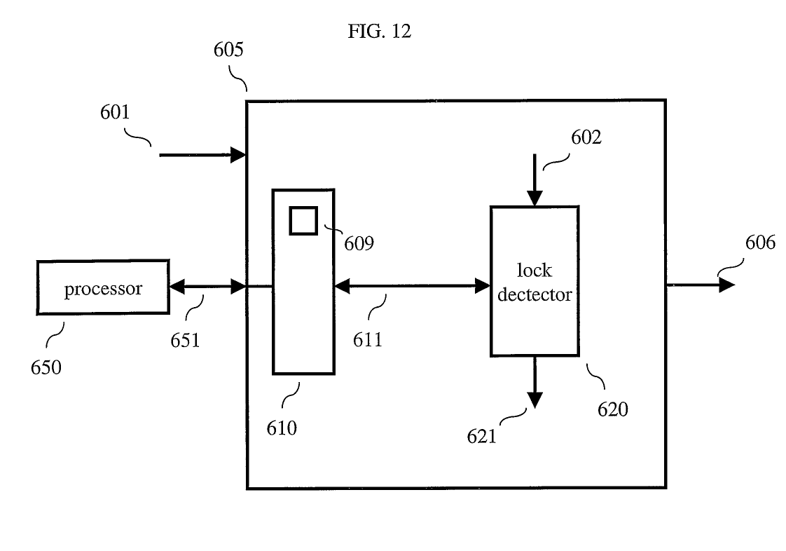

Another illustrative embodiment of the inventive concept is shown in FIG. 12. In this illustrative embodiment an integrated circuit (IC) 605 for use in a receiver (not shown) includes a lock detector 620 and at least one register 610, which is coupled to bus 651. Illustratively, IC 605 is an integrated analog/digital television decoder. However, only those portions of IC 605 relevant to the inventive concept are shown. For example, analog-digital converters, filters, decoders, etc., are not shown for simplicity. Bus 651 provides communication to, and from, other components of the receiver as represented by processor 650. Register 610 is representative of one, or more, registers, of IC 605, where each register comprises one, or more, bits as represented by bit 609. The registers, or portions thereof, of IC 605 may be read-only, write-only or read/write. In accordance with the principles of the invention, lock detector 620 includes the above-described equalizer lock detector feature, or operating mode, and at least one bit, e.g., bit 609 of register 610, is a programmable bit that can be set by, e.g., processor 650, for enabling or disabling this operating mode. In the context of FIG. 12, IC 605 receives an IF signal 601 for processing via an input pin, or lead, of IC 605. A derivative of this signal, 602, is applied to lock detector 620 for equalizer lock detection as described above. Lock detector 620 provides signal 621, which is indicative of whether or not the equalizer (not shown in FIG. 12) is locked. Although not shown in FIG. 12, signal 621 may be provided to circuitry external to IC 605 and/or be accessible via register 610. Lock detector 620 is coupled to register 610 via internal bus 611, which is representative of other signal paths and/or components of IC 605 for interfacing lock detector 620 to register 610 as known in the art (e.g., to read the earlier-described integrator and counter values). IC 605 provides one, or more, recovered signals, e.g., a composite video signal, as represented by signal 606. It should be noted that other variations of IC 605 are possible in accordance with the principles of the invention, e.g., external control of this operating mode, e.g., via bit 610, is not required and IC 605 may simply always perform the above-described processing for detecting equalizer lock.

As described above, and in accordance with the principles of the invention, a receiver determines equalizer lock as a function of a noise power estimate, which is determined as a function of the distribution of received signal points in a constellation space, wherein different weights are given to different regions of the constellation space. It should be noted that although the inventive concept was described in terms of a weight value of zero (i.e., no weight) being given to received signal points falling within an inner region and a weight value of one being given to received signal points falling in an outer region, the inventive concept is not so limited. Likewise, although the inventive concept was described in the context of an outer region and an inner region, the inventive concept is not so limited.

In view of the above, the foregoing merely illustrates the principles of the invention and it will thus be appreciated that those skilled in the art will be able to devise numerous alternative arrangements which, although not explicitly described herein, embody the principles of the invention and are within its spirit and scope. For example, although illustrated in the context of separate functional elements, these functional elements may be embodied on one or more integrated circuits (ICs). Similarly, although shown as separate elements, any or all of the elements of may be implemented in a stored-program-controlled processor, e.g., a digital signal processor, which executes associated software, e.g., corresponding to one or more of the steps shown in, e.g., FIGS. 5 and/or 6, etc. Further, although shown as elements bundled within TV set 10, the elements therein may be distributed in different units in any combination thereof. For example, receiver 15 of FIG. 3 may be a part of a device, or box, such as a set-top box that is physically separate from the device, or box, incorporating display 20, etc. Also, it should be noted that although described in the context of terrestrial broadcast, the principles of the invention are applicable to other types of communications systems, e.g., satellite, cable, etc. It is therefore to be understood that numerous modifications may be made to the illustrative embodiments and that other arrangements may be devised without departing from the spirit and scope of the present invention as defined by the appended claims.

1. A method for use in a receiver including an equalizer, comprising:
providing an input for receiving a sequence of received signal points in a constellation space;
determining a noise power estimate as a function of the distribution of the received signal points, wherein different weights are given to different regions of the constellation space; and
determining equalizer lock as a function of the noise power estimate.

2. The method of claim 1, wherein an outer region is weighted more than an inner region of the constellation space.

3. The method of claim 1, wherein the determining a noise power estimate step includes the step of:
giving no weight to those received signal points falling in one, or more, inner regions of the constellation space.

4. The method of claim 3, wherein the determining equalizer lock step includes the step of:
if the determined noise power estimate is less than a threshold, determining that equalizer lock has occurred.

5. The method of claim 3, wherein at least one of the outer regions is a corner region of the constellation space.

6. The method of claim 1, wherein the determining equalizer lock step includes the steps of:
determining a signal-to-noise ratio (SNR) estimate from the noise power estimate; and
if the SNR estimate is larger than a threshold, determining that the equalizer is locked

7. The method of claim 1, wherein the constellation space is an M-VSB (vestigial sideband) symbol constellation.

8. The method of claim 1, wherein the constellation space is an M-QAM (quadrature amplitude modulated) symbol constellation.

9. The method of claim 1, wherein at least one of the regions is a corner region of the constellation space.

10. A receiver, comprising:
an equalizer for providing a sequence of received signal points; and
a lock detector;
wherein the lock detector determines equalizer lock as a function of a noise power estimate, which is determined as a function of the distribution of received signal points in a constellation space, wherein different weights are given to different regions of the constellation space.

11. The receiver of claim 10, wherein an outer region is weighted more than an inner region of the constellation space.

12. The receiver of claim 10, wherein the lock detector gives no weight to those received signal points falling in one, or more, inner regions of the constellation space.

13. The receiver of claim 12, wherein the lock detector determines a value for the noise power estimate, and, if the determined value is less than a threshold, determines that equalizer lock has occurred.

14. The receiver of claim 12, wherein at least one of the regions is a corner region of the constellation space.

15. The receiver of claim 10, wherein the lock detector determines a signal-to-noise ratio (SNR) estimate from the noise power estimate, and, if the SNR estimate is larger than a threshold, determines that the equalizer is locked

16. The receiver of claim 10, wherein the constellation space is an M-VSB (vestigial sideband) symbol constellation.

17. The receiver of claim 10, wherein the constellation space is an M-QAM (quadrature amplitude modulated) symbol constellation.

18. The receiver of claim 10, wherein at least one of the regions is a corner region of the constellation space.

19. A receiver comprising:
a decoder for processing a received signal, wherein the decoder determines equalizer lock as a function of signal points derived from the received signal; and
a processor for controlling the decoder such that the decoder determines equalizer lock as a function of a noise power estimate, which is determined as a function of the distribution of received signal points in a constellation space, wherein different weights are given to different regions of the constellation space.

20. The receiver of claim 19, wherein an outer region is weighted more than an inner region of the constellation space.

21. The receiver of claim 19, wherein the decoder gives no weight to those received signal points falling in one, or more, inner regions of the constellation space.

22. The receiver of claim 21, wherein the lock detector determines a value for the noise power estimate, and, if the determined value is less than a threshold, determines that equalizer lock has occurred.

23. The receiver of claim 21, wherein at least one of the regions is a corner region of the constellation space.

24. The receiver of claim 19, wherein the decoder determines a signal-to-noise ratio (SNR) estimate from the noise power estimate, and, if the SNR estimate is larger than a threshold, determines that the equalizer is locked

25. The receiver of claim 19, wherein the constellation space is an M-VSB (vestigial sideband) symbol constellation.

26. The receiver of claim 19, wherein the constellation space is an M-QAM (quadrature amplitude modulated) symbol constellation.

27. The receiver of claim 19, wherein at least one of the regions is a corner region of the constellation space.
